(19) United States
(12) Patent Application Publication
(10) Pub. No.: US 2022/0082670 A1
(43) Pub. Date: Mar. 17, 2022

(54) TOF OPTICAL SENSING MODULE WITH ANGULAR LIGHT-GUIDING STRUCTURE

(71) Applicant: Egis Technology Inc., Hsinchu City (TW)

(72) Inventors: Bruce C.S. CHOU, Hsinchu City (TW); CHEN-CHIH FAN, Hsinchu City (TW)

(21) Appl. No.: 17/459,665

(22) Filed: Aug. 27, 2021

Related U.S. Application Data
(60) Provisional application No. 63/077,050, filed on Sep. 11, 2020.
(60) Provisional application No. 63/094,568, filed on Oct. 21, 2020.

(30) Foreign Application Priority Data
Aug. 19, 2021 (CN) 202110953004.1

(51) Int. Cl. G01S 7/4865; G01S 17/894; H01L 31/107; G01S 7/4861

(52) U.S. Cl. CPC G01S 7/4865; G01S 7/4861; H01L 31/107; G01S 17/894

(57) ABSTRACT

A TOF optical sensing module includes: a substrate; a cap having a body and a receiving window and a transmitting window both connected to the body, wherein the body and the substrate commonly define a chamber; and a transceiving unit being disposed in the chamber and including: a light sensing region being disposed beneath the receiving window and including an angular sensing-end light-guiding structure and at least a sensing pixel, wherein the angular sensing-end light-guiding structure is configured to stop reference light, coming from the chamber and a location below the transmitting window, from entering the sensing pixel, but allow sensing light to be received by the sensing pixel through the receiving window to generate an electric sensing signal.

### CROSS-REFERENCE TO RELATED APPLICATIONS

This application claims priorities of U.S. Provisional Patent Application Ser. No. 63/077,050, filed on Sep. 11, 2020; and 63/094,568, filed on Oct. 21, 2020; and China Patent Application Ser. No. 202110953004.1, filed on Aug. 19, 2021, the entire contents of which are hereby incorporated by reference.

### BACKGROUND OF THE INVENTION

### Field of the Invention

This disclosure relates to a time of flight (TOF) optical sensing module, and more particularly to a TOF optical sensing module with an angular light-guiding structure.

### Description of the Related Art

Today's smart phones, tablet computers or other handheld devices are equipped with optical modules to achieve gesture detecting, three-dimensional (3D) imaging proximity detecting or camera focusing and other functions. The TOF sensor emits near infrared light toward the scene to measure the distance from the object in the scene according to the TOF information of light. The advantages of the TOF sensor include the small depth information calculation loading, the strong anti-interference and the long measurement range, so it has gradually been favored.

The core components of the TOF sensor include: a light source, more particularly an infrared vertical cavity surface emitting laser (VCSEL); a photosensor, more particularly a single photon avalanche diode (SPAD); and a time-to-digital converter (TDC). The SPAD is a photoelectric detection avalanche diode having the single photon detection ability of generating a current as long as a weak optical signal is received. The VCSEL in the TOF sensor emits a pulse wave to the scene, the SPAD receives the pulse wave reflected back from the object, the TDC records the time interval between the time of emitting and receiving the pulses, and the depth information of the to-be-measured object is calculated according to the TOF.

FIG. 1 is a schematic view showing a conventional TOF optical sensing module 300. Referring to FIG. 1, the TOF optical sensing module 300 includes a cap 310, a light-emitting unit 320, a sensor chip 330 and a substrate 350. The substrate 350, such as a printed circuit board, includes one or multiple insulating layers and one or multiple electroconductive layers (not shown). The light-emitting unit 320 and the sensor chip 330 are disposed above the substrate 350 through an adhesive material. The light-emitting unit 320 and the sensor chip 330 are electrically connected to the substrate 350. At least one reference pixel 331 and at least a sensing pixel 341 are formed on the sensor chip 330. The optical sensing module 300 further includes a control processing circuit, such as an integrated circuit, for controlling the light-emitting unit 320 to emit light, controlling the reference pixel 331 to receive light, controlling the sensing pixel 341 to receive light and processing electric signals generated after the reference pixel 331 and the sensing pixel 341 have received the light. The cap 310 has a transmitting window 314 and a receiving window 312, and is disposed above the substrate 350 to accommodate the light-emitting unit 320 and the sensor chip 330 on the substrate 350 within a chamber 315 of the cap 310. The light-emitting unit 320 outputs detection light L1 to the object (not shown) through the transmitting window 314, and the sensing pixel 341 receives sensing light L3 reflected from the object through the receiving window 312. The detection light L1 is reflected by the cap 310 to generate reference light L2 travelling toward the reference pixel 331, so the reference light L2 is also known as in-chamber reflected light. It is understood that a portion of the reference light L2 is continuously reflected in the chamber 315 and then received by the sensing pixel 341, thereby interfering with the sensing result of the sensing pixel 341. Thus, how to reduce the noise interference is an issue to be solved by this disclosure.

### BRIEF SUMMARY OF THE INVENTION

It is therefore an objective of this disclosure to provide a TOF optical sensing module with an angular light-guiding structure, wherein an angular sensing-end light-guiding structure in a chamber is configured such that the interference of stray light transmitted in the chamber of the sensing module can be minimized, the signal-to-noise ratio (SNR) of the sensing pixel can be increased, the interference of the in-chamber stray light to the sensing pixel can be decreased, and the distance sensing result becomes more stable and accurate.

An objective of this disclosure is to provide a TOF optical sensing module with an angular light-guiding structure, wherein different fields of view (FOVs) of the same optical sensing module are utilized to sense different objects from different distances to obtain corresponding distance information.

To achieve the above-identified objects, this disclosure provides a TOF optical sensing module including: a substrate; a cap having a body and a receiving window and a transmitting window both connected to the body, wherein the body and the substrate commonly define a chamber; and a transceiving unit being disposed in the chamber and including: a light sensing region being disposed beneath the receiving window and including an angular sensing-end light-guiding structure and at least a sensing pixel, wherein the angular sensing-end light-guiding structure is configured to stop reference light, coming from the chamber and a location below the transmitting window, from entering the sensing pixel, but allow sensing light to be received by the sensing pixel through the receiving window to generate an electric sensing signal.

To achieve the above-identified objects, this disclosure further provides a TOF optical sensing module including: a substrate; a cap being disposed on the substrate and having a receiving window and a transmitting window, wherein the cap and the substrate commonly define a chamber; and a transceiving unit disposed on the substrate and in the chamber, wherein the transceiving unit includes a light-emitting unit and multiple sensing cells, the light-emitting unit outputs detection light through the transmitting window, and the sensing cells have different angular ranges of FOVs.

With the above-mentioned TOF optical sensing module, at least a specific angular light-guiding structure is adopted to minimize the interference of stray light transmitted in the chamber of the sensing module to increase the SNR of the sensing pixel, and to enhance the optical sensing stability. In addition, using different angular ranges of FOVs provided by different angular light-guiding structures of one single optical sensing module can provide multiple distance ranges of sensing effects and obtain different distance information of the objects, so that the increasingly diversified applications can be provided.

In order to make the above-mentioned summary of this disclosure become more obvious and understandable, a detailed description of the preferred embodiments will be provided in the following in conjunction with the accompanying drawings.

### BRIEF DESCRIPTION OF THE SEVERAL VIEWS OF THE DRAWINGS

FIG. 1 is a schematic view showing a conventional TOF optical sensing module.

FIGS. 2A and 2B are schematic views showing two examples of TOF optical sensing modules according to a preferred embodiment of this disclosure.

FIG. 3 is a schematically partial cross-sectional view showing the TOF optical sensing module of FIG. 2B.

FIGS. 4 to 6 are schematically partial cross-sectional views showing modified examples of the TOF optical sensing module of FIG. 3.

FIGS. 7A-7B and FIGS. 8A-8B are schematic views showing modified examples of the TOF optical sensing module of FIG. 2B.

FIG. 9 is a schematic view showing a modified example of the TOF optical sensing module of FIG. 7B.

FIG. 10 is a schematic view showing a TOF optical sensing module according to a preferred embodiment of this disclosure.

FIG. 11 shows schematic structures of two sensing cells of FIG. 10.

FIG. 12 shows schematic structures of modified examples of the two sensing cells of FIG. 11.

FIG. 13 is a schematic view showing light paths of a modified example of FIG. 10.

FIGS. 14 and 15 show layouts of two examples of sensing cells.

FIG. 16 is a schematic view showing FOVs of sensing cells.

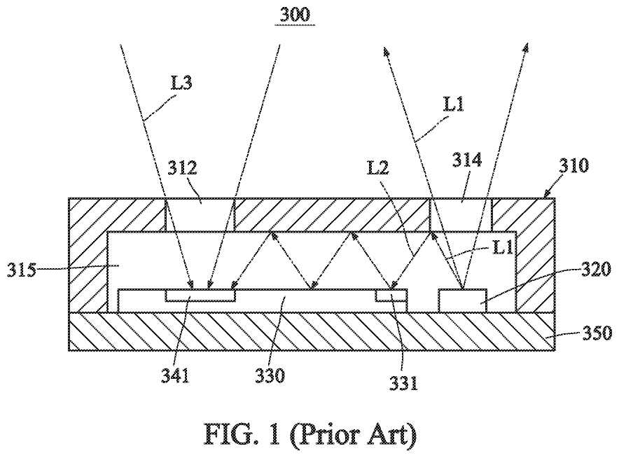

### DETAILED DESCRIPTION OF THE INVENTION

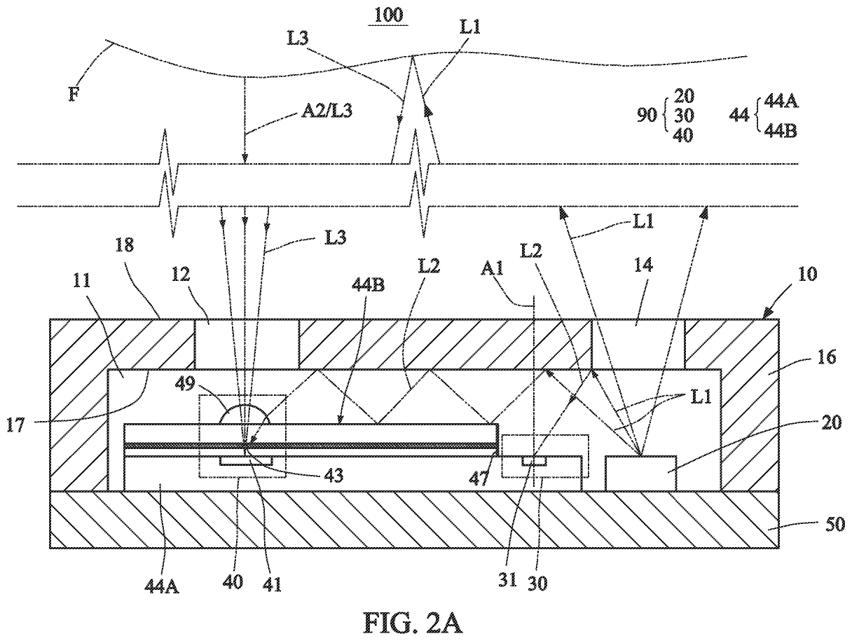

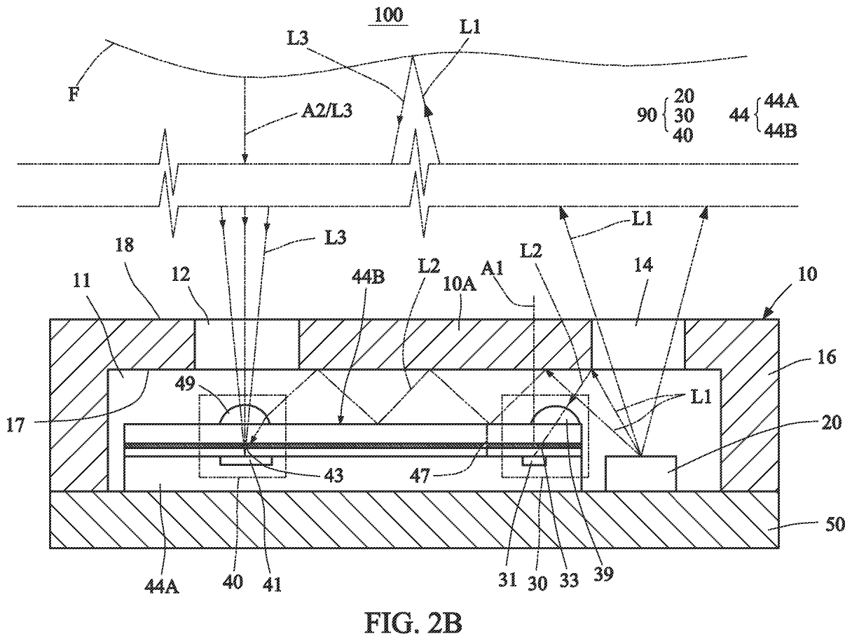

In one aspect of this disclosure, a wafer-scale manufacturing process is adopted to form at least a specific angular light-guiding structure on a surface of a photosensitive chip (see FIGS. 2A to 6) so as to minimize the interference of stray light transmitted in a package body structure, to increase the signal-to-noise ratio (SNR) of the sensing pixel, and thus to solve the conventional problems. In one specific example having two specific angular light-guiding structures, a wafer-scale manufactured micro-lens is used in conjunction with a wafer-scale manufactured light-obstructing layer to form an angular reference-end light-guiding structure to guide in-chamber reflected light, which is usually oblique incident light, into a reference pixel. Meanwhile, an angular sensing-end light-guiding structure is formed to prevent the in-chamber reflected light from entering the sensing pixel, so that in-chamber reflected stray light can be avoided, or even a lot of external stray light from every orientation can be stopped from entering the sensing pixel, so that the TOF detection and calculation process can be simplified, and the precise depth information or distance information can be obtained.

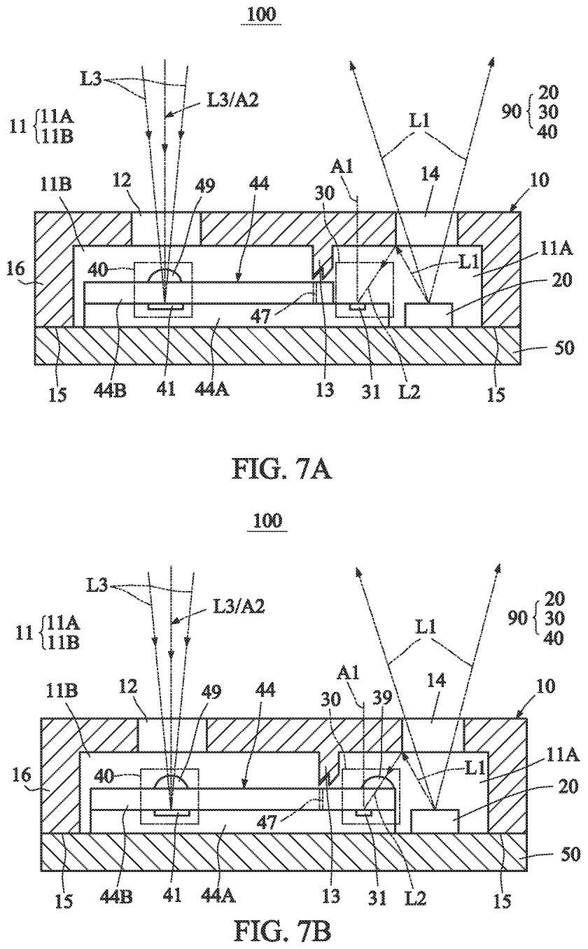

In another aspect of this disclosure, a package process, which may also be the wafer-scale package process, is adopted to form a stopper structure on an inner side of a package cap and to form a receiving chamber and an emitting chamber partially communicating with each other (see FIGS. 7A to 9), so that the manufacturing process can be easily controlled and simplified, the structural stability can be enhanced, the environment condition difference between the receiving chamber and the emitting chamber can be decreased, the optical sensing stability can be enhanced, the stray light interference can be decreased, and the SNR of the sensing pixel can be increased.

In still another aspect of this disclosure, multiple sensing cells having different FOVs are integrated on one sensor chip, wherein sensing cells having different angular sensing-end light-guiding structures are utilized to sense objects at different distances to obtain the multi-FOV sensing function using one single TOF optical sensing module and to obtain multiple distance ranges of sensing effects. It is understood that the three aspects can be adopted individually or in combined manners.

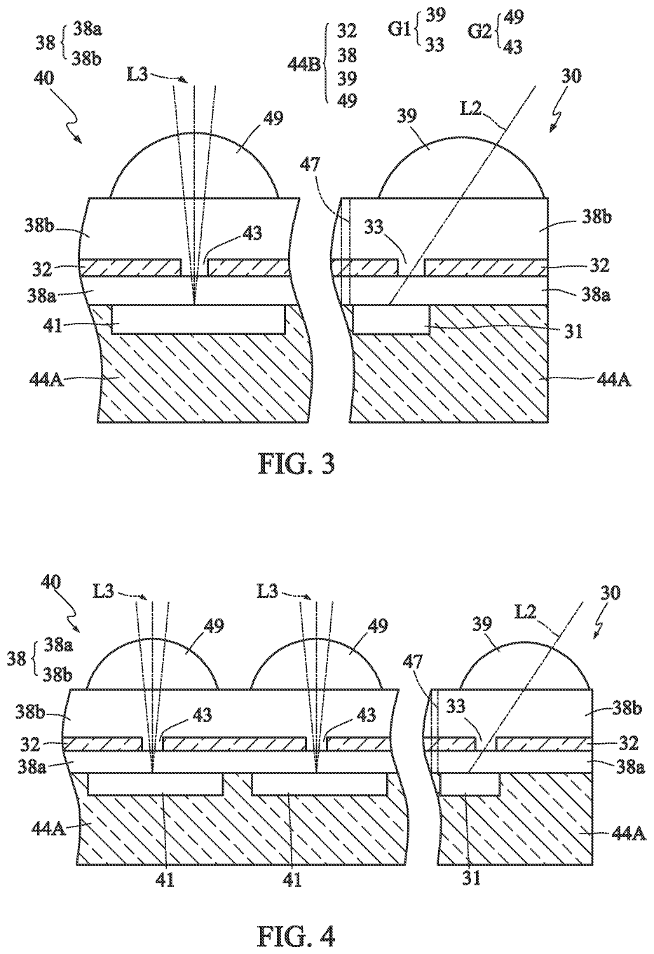

FIGS. 2A and 2B are schematic views showing two examples of TOF optical sensing modules according to a preferred embodiment of this disclosure. FIG. 3 is a schematically partial cross-sectional view showing the TOF optical sensing module of FIG. 2B. The difference between FIGS. 2A and 2B resides in that no corresponding angular light-guiding structure is disposed above the reference pixel of FIG. 2A. Referring to FIG. 2A, a TOF optical sensing module 100 includes a cap 10 and a transceiving unit 90. The transceiving unit 90 includes a light-emitting unit 20, a light sensing region 40 and an optional light reference region 30, wherein the light reference region 30 is closer to the light-emitting unit 20 while the light sensing region 40 is farther away from the light-emitting unit 20. In this example, the light sensing region 40 and the light reference region 30 are formed in a sensing chip 44. In another example, however, the light sensing region 40 and the light reference region 30 may be formed on different chips. From another point of view, the sensing chip 44 includes a pixel substrate 44A and an angular light-guiding structure 44B disposed above the pixel substrate 44A. At least one reference pixel 31 of the light reference region 30 is formed in the pixel substrate 44A and for receiving light; and at least a sensing pixel 41 of the light sensing region 40 is formed in the pixel substrate 44A, and for receiving a specific angular range of light through the angular light-guiding structure 44B. A portion of the pixel has a photosensitive structure, such as a photodiode, an avalanche photodiode (APD) and the like, which is the SPAD in this embodiment. The other portion of the pixel has a sensing circuit for processing an electric signal coming from the photosensitive structure. The sensing chip 44 may be manufactured using, for example, a complementary metal-oxide semiconductor (CMOS) manufacturing process, such as a front side illumination (FSI) or a back side illumination (BSI) manufacturing process, or any other semiconductor manufacturing process. However, this disclosure is not restricted thereto. In addition, the TOF optical sensing module 100 may further include a substrate 50, on which the transceiving unit 90 is disposed. The light-emitting unit 20 and the light reference region 30 and the light sensing region 40 of the sensing chip 44 are disposed on the substrate 50. The cap 10 has an inverse U-shaped structure to cover the substrate 50 to form a chamber 11, so that the light-emitting unit 20, the light reference region 30 and the light sensing region 40 are accommodated within the chamber 11. The substrate 50 includes one or multiple insulating layers and one or multiple electroconductive layers, and may be one of a printed circuit board, a ceramic substrate and the like.

The material of the pixel substrate 44A may include a semiconductor material, such as silicon, germanium, gallium nitride, silicon carbide, gallium arsenide, gallium phosphide, indium phosphide, indium arsenide, indium antimonide, silicon germanium alloy, gallium arsenide phosphide alloy, aluminum indium arsenic alloy, aluminum gallium arsenic alloy, gallium indium arsenic alloy, gallium indium phosphide alloy, gallium indium arsenic phosphide alloy or a combination of the above-mentioned materials. The pixel substrate may further include one or multiple electrical components (e.g., integrated circuits). The integrated circuit may be an analog circuit or a digital circuit, which may be implemented and formed in the chip to achieve the electrical connections according to the electrical design and the function of the chip and may include an active device, a passive device, an electroconductive layer, a dielectric layer and the like. The pixel substrate may be electrically connected to the substrate 50 through bonding wires or electroconductive bumps, and thus electrically connected to an external device and the light-emitting unit 20 to control operations of the light-emitting unit 20, the light reference region 30 and the light sensing region 40 and to provide a signal processing function.

The cap 10 includes an opaque body 16 and a receiving window 12 and a transmitting window 14, each of which is connected to the body 16 and has a light-transmission region through which the to-be-measured light is transmitted. The body 16 and the substrate 50 commonly define the chamber 11, an inner surface 17 covering and defining the chamber 11 and an outer surface 18 exposed to the external environment. In one example, the chamber 11 is a solid body made of a light-transmission molding compound, and the body 16 is made of an opaque material, such as an opaque molding compound, metal and the like, and covers the chamber 11 of the light-transmission molding compound with a portion of the light-transmission molding compound corresponding to each of the receiving window 12 and the transmitting window 14 being exposed. In another example, the chamber 11 may be filled with air with the pressure higher than or lower than one atmosphere. It can be understood that the cap 10 of this embodiment can be previously formed and adhered to the substrate 50. For example, the cap 10 can be directly and partially or entirely formed on the substrate 50 by way of injection molding. The receiving window 12 and the transmitting window 14 may be hollow openings, may be optical devices having special optical functions, such as optical filters of specific wavelengths, lenses or diffractive elements with the light defocusing or focusing function, and the like, or may be combinations of elements with multiple optical functions, such as the former two elements.

The light-emitting unit 20 is disposed on the substrate 50, is correspondingly disposed beneath the transmitting window 14, and outputs detection light L1. One portion of the detection light L1 travels by a distance through the transmitting window 14, then irradiates an object F above the cap 10, and then reflected from the object F to output sensing light L3, wherein the object F may be an organism object or a non-organism object. A portion of the sensing light L3 coming from the outside of the chamber 11 passes through the receiving window 12 and is received by the light sensing region 40 of the sensing chip 44 and converted into the electric signal by the light sensing region 40. The light sensing region 40 is disposed beneath the receiving window 12, and receives the sensing light L3 through the receiving window 12 to generate an electric sensing signal. However, the distance to the object F needs to be calculated according to the time instant when the light sensing region 40 receives the signal with reference to a reference time instant. According to the TOF formula, 2L=C A t is obtained, where L denotes the distance from the optical sensing module 100 to the object F, C denotes the speed of light, and At denotes the travelling time of light (herein defined as the time difference between the emitting time and the receiving time). Therefore, in addition to obtaining the time instant when the light sensing region 40 receives the sensing light L3, the start time instant when the light reference region 30 emits the detection light L1 also needs to be obtained. In another example, however, it is also possible to take the time instant, at which the light-emitting unit 20 is controlled to emit light, as the start time instant, at which the detection light L1 is emitted, or take the start time instant plus a predetermined delay time as the basis for the TOF calculation. Because the light-emitting unit 20 has a predetermined divergence angle, another portion of the detection light L1 is reflected within the chamber 11 of the cap 10 to generate reference light L2, and a specific angle of the reference light L2 is received by the light reference region 30, so that the start time instant is obtained, wherein the travelling distance of the light reflected in the package body structure can be neglected when compared with the distance (2L) of the object, so the time instant at which the light reference region 30 receives the reference light L2 can be set as the start time instant. Thus, the transceiving unit 90 disposed in the chamber 11 outputs the detection light L1 passing through the transmitting window 14, and receives the sensing light L3 through the receiving window 12. In one example, the light-emitting unit 20 is configured to emit the radiation (e.g., infrared (IR) light) with a specific frequency or frequency range. In several examples, the light-emitting unit 20 is the VCSEL or a light-emitting diode (LED), such as an infrared LED. The light-emitting unit 20 may be attached to the upper surface of the substrate 50 through an adhesive material, and can be electrically connected to the substrate 50 through bonding wires or electroconductive bumps, for example. The sidewall of the angular light-guiding structure 44B in FIG. 2A is provided with a longitudinal light blocking structure 47 for stopping stray light from entering the angular light-guiding structure 44B to avoid the interference. Although the reference light L2, coming from the chamber 11 and a location beneath the transmitting window 14, travels toward the light sensing region 40, the reference light L2 cannot enter the sensing pixel 41 due to the configuration of the light-guiding structure 44B. In one example, the configuration of the light-guiding structure 44B is the same as that of FIG. 2B, so the explanation will be made with reference to FIGS. 2B and 3.

Referring to FIGS. 2B and 3, the light reference region 30 is disposed at a location close the light-emitting unit 20 in the chamber 11, and is disposed beneath an opaque region 10A of the cap 10, which is disposed between the transmitting window 14 and the receiving window 12 of the light-transmission region, and further includes an angular reference-end light-guiding structure G1 being formed on the pixel substrate 44A and constituting a portion of the angular light-guiding structure 44B. The light-guiding structure G1 includes a first reference aperture 33 of at least a first light-obstructing layer 32 and at least a reference micro-lens 39 disposed above the reference pixel 31, and guides the reference light L2 to the reference pixel 31, so that the reference pixel 31 receives the reference light L2 and generates an electric reference signal. The first light-obstructing layer 32 may be made of a metal material or a non-metal material. The reference micro-lens 39 is disposed above the first reference aperture 33 of the first light-obstructing layer 32. In this embodiment, the center line of the reference micro-lens 39 is configured to be mis-aligned with the center line of the first reference aperture 33, so that the reference light L2 with a first specific angular range can be focused onto the reference pixel 31 through the reference micro-lens 39 and the first reference aperture 33. Thus, the reference micro-lens 39 and the first reference aperture 33 can provide an angle controllable collimator (ACC) functioning as the angular reference-end light-guiding structure G1 of the light reference region 30.

Referring to FIGS. 2A, 2B, 3 and 4, the light sensing region 40 is disposed beneath the receiving window 12, and further includes an angular sensing-end light-guiding structure G2 including a first sensing aperture 43 of the first light-obstructing layer 32 and at least a sensing micro-lens 49, wherein FIG. 4 is only used for explaining that the light sensing region 40 may have more than two sensing pixels 41 and more than two sensing micro-lenses 49, and that the reference light L2 may be regarded as coming from one side of the angular sensing-end light-guiding structure G2. The sensing micro-lens 49 is disposed above the first sensing aperture 43 of the first light-obstructing layer 32. The center line of the sensing micro-lens 49 is aligned with the center line of the first sensing aperture 43. Herein, the alignment configuration of the center lines is described as a non-restrictive example. In addition, the sensing light L3 is focused onto the sensing pixel 41 through the sensing micro-lens 49 and the first sensing aperture 43. In the example of FIGS. 3 and 4, the sensing light L3 is focused onto the sensing pixel 41 through the sensing micro-lens 49 and the first sensing aperture 43. The light-guiding structure 44B includes a transparent dielectric layer set 38, the first light-obstructing layer 32, the reference micro-lens 39 and the sensing micro-lens 49, and the light sensing region 40 and the light reference region 30 are integrated into an integral structure. Therefore, the sensing micro-lens 49 and the first sensing aperture 43 can provide another ACC functioning as the angular sensing-end light-guiding structure G2 of the light sensing region 40. Because the optical structures of the light sensing region and the light reference region can be concurrently formed by the wafer-scale manufacturing process in this disclosure, the light-obstructing layer or micro-lens may be formed by the same manufacturing process.

It is understood that the reference pixel(s) 31 and the sensing pixel(s) 41 may be individually configured into one single point, a one-dimensional array or a two-dimensional array. The light reference region 30 receives the first specific angular range of the reference light L2 reflected from the cap 10, and converts the reference light L2 into the electric reference signal. The light sensing region 40 receives the second specific angular range of the sensing light L3 coming from the object F, and converts the sensing light L3 into an electric sensing signal. In one example, the light reference region 30 receives the reference light L2 reflected from the cap 10 at a first time instant T0 and performs opto-electronic conversion to generate the electric reference signal, wherein the reference light L2 is the oblique light with respect to a first optical axis A1 of the light reference region 30. In addition, the light sensing region 40 is configured to receive, at a second time instant T1, the sensing light L3 outputted from the object F and performs opto-electronic conversion to generate the electric sensing signal, wherein the sensing light L3 is the second specific angular range of light with respect to a second optical axis A2 of the light sensing region 40, and the two specific angular ranges are different from each other. Although the reference light L2 may be reflected between the sensing chip 44 and the cap 10 and reach a location near the light sensing region 40, the specific ACC configuration of the light sensing region 40 can prevent the sensing pixel 41 from receiving the reference light L2. The distance from the object F to the TOF optical sensing module 100 can be obtained by the control processing circuit according to the TOF formula, the first time instant T0, the second time instant T1 and the speed C of light. In this example, although the depicted sensing light L3 having angular ranges is symmetrical about the incident normal perpendicular to the surface of the sensing pixel 41, and has the left boundary and right boundary at the same angle with respect to the incident normal, this disclosure is not restricted thereto. In another example, the sensing light may be asymmetrical about the incident normal and has the left boundary and right boundary at different angles with respect to the incident normal. In still another example, the angular range of the sensing light is disposed on only the left side or the right side of the incident normal.

In FIGS. 3 and 4, the transparent dielectric layer set 38 includes transparent dielectric layers 38a and 38b. The transparent dielectric layer 38a is disposed between the reference pixel 31 and the first light-obstructing layer 32, and the transparent dielectric layer 38b is disposed between the first light-obstructing layer 32 and the reference micro-lens 39. In addition, the transparent dielectric layer 38a is also disposed between the sensing pixel 41 and the first light-obstructing layer 32, and the transparent dielectric layer 38b is also disposed between the first light-obstructing layer 32 and the sensing micro-lens 49. Therefore, the transparent dielectric layer set 38 may be present in a single-layer material or a multi-layer structure. In one example, the material of the transparent dielectric layer may be a dielectric material or a transparent polymer, such as SiO₂, and the like. In another example, the transparent dielectric layer may include a light-curing material (e.g., UV-curable material), a thermosetting material or combinations thereof. For example, the transparent dielectric layer may include, for example, polymethylmethacrylate (PMMA), polyethylene terephthalate (PET), polyethylene naphthalate (PEN), polycarbonate (PC), perfluorocyclobutyl (PFCB) polymer, polyimide (PI), acrylic resin, epoxy resin, polypropylene (PP), polyethylene (PE), polystyrene (PS), polyvinyl chloride (PVC), other appropriate materials or combinations thereof. However, this disclosure is not restricted thereto. In another embodiment, a longitudinal light blocking structure 47 may be formed in the transparent dielectric layer set 38 between the light sensing region 40 and the light reference region 30 to stop the stray light from entering the sensing pixel 41 and the reference pixel 31. The longitudinal light blocking structure 47 is separated from the cap 10 by a distance, and disposed between the light reference region 30 and the light sensing region 40 to prevent the stray light interference between the light reference region 30 and the light sensing region 40. The longitudinal light blocking structure 47 may include a metal material or a non-metal material. It is understood that the longitudinal light blocking structure 47 is optional.

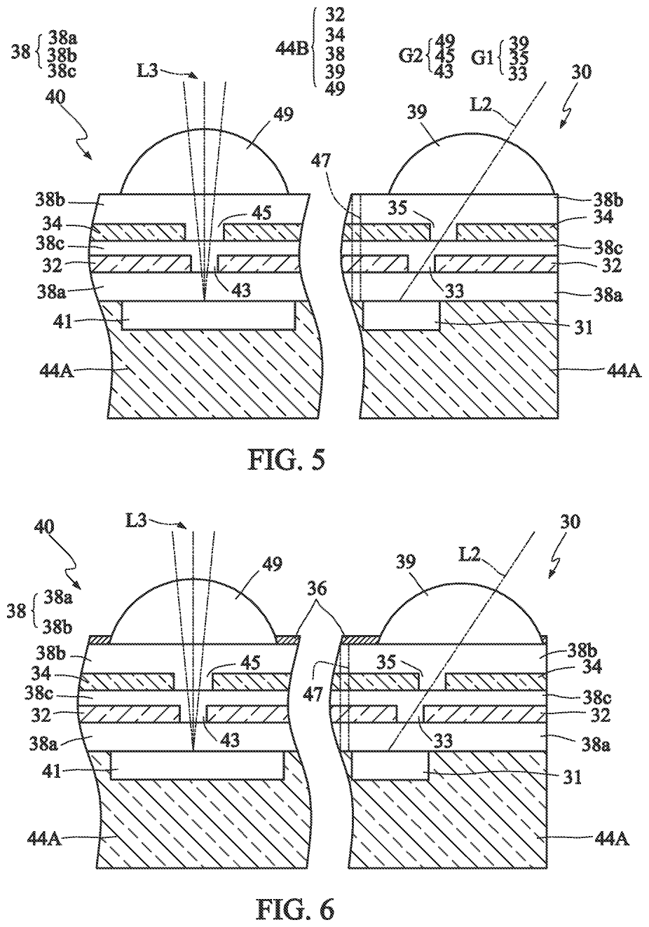

Referring to FIG. 5, this example is similar to FIG. 3 except for the difference that the light reference region 30 and the light sensing region 40 further include a second light-obstructing layer 34, and the transparent dielectric layer set 38 includes transparent dielectric layers 38a, 38b and 38c. The second light-obstructing layer 34 pertains to a portion of the angular sensing-end and reference-end light-guiding structures, is disposed above the first light-obstructing layer 32, and has a second reference aperture 35 and a second sensing aperture 45. The transparent dielectric layer 38a is disposed between the reference pixel 31 and the first light-obstructing layer 32 and disposed between the sensing pixel 41 and the first light-obstructing layer 32, the transparent dielectric layer 38b is disposed between the reference micro-lens 39 and the second light-obstructing layer 34 and disposed between the sensing micro-lens 49 and the second light-obstructing layer 34, and the transparent dielectric layer 38c is disposed between the second light-obstructing layer 34 and the first light-obstructing layer 32. It is to be noted that the architecture of the sensing pixels 41 of FIG. 4 may also be applied to FIG. 5. In this case, no alignment is present between the center line of the reference micro-lens 39, the center line of the first reference aperture 33 and the center line of the second reference aperture 35, and the reference light L2 is focused onto the reference pixel 31 through the reference micro-lens 39, the second reference aperture 35 and the first reference aperture 33. Therefore, the angular reference-end light-guiding structure G1 includes the reference micro-lens 39, the first reference aperture 33 and the second reference aperture 35. Similarly, the center line of the sensing micro-lens 49, the center line of the first sensing aperture 43 and the center line of the second sensing aperture 45 have the aligned relationships. Consequently, the sensing light L3 may be focused onto the sensing pixel 41 through the sensing micro-lens 49, the second sensing aperture 45 and the first sensing aperture 43. Therefore, the angular sensing-end light-guiding structure G2 includes the sensing micro-lens 49, the first sensing aperture 43 and the second sensing aperture 45, stops the reference light L2 from entering the sensing pixel 41, and guides the sensing light L3 to the sensing pixel 41 (the sensing light L3 received through the receiving window 12 enters the sensing pixel 41), so that the sensing pixel 41 generates the electric sensing signal.

Referring to FIG. 6, this example is similar to FIG. 5 except for the difference that the light reference region 30 and the light sensing region 40 further include a third light-obstructing layer 36, which also pertains to a portion of the angular sensing-end and reference-end light-guiding structures. The third light-obstructing layer 36 is disposed above the second light-obstructing layer 34, and on peripheries of the reference micro-lens 39 and the sensing micro-lens 49 to block the stray light from entering the reference pixel 31 and the sensing pixel 41. The architecture of the sensing pixels 41 of FIG. 4 may also be applied to FIG. 6.

Each of the first to third light-obstructing layers may include the metal material (such as the last metal material in the integrated circuit manufacturing process), such as tungsten (W), chromium (Cr), aluminum (Al), titanium (Ti) and the like. The light-obstructing layer may be formed in a blanket manner through chemical vapor deposition (CVD), physical vapor deposition (PVD) (e.g., vacuum evaporation process, sputtering process, pulsed laser deposition (PLD)), atomic layer deposition (ALD) any other suitable deposition process or combinations thereof, for example. In some embodiments, the light-obstructing layer may include a light-obstructing polymeric material, such as epoxy resin, polyimide or the like.

In another example, it is also possible to further stop or restrict the reference light L2 from reaching the light sensing region 40 in conjunction with the structural design of the cap 10. Referring to FIG. 7A, the cap 10 may further include a stopper structure 13. The stopper structure 13 is connected to the body 16 of the cap 10 and disposed between the first optical axis A1 and the second optical axis A2, disposed between the light sensing region 40 and the light reference region 30, or disposed between the transmitting window 14 and the receiving window 12. The sensing chip 44 is separated from the stopper structure 13 in a longitudinal direction. Of course, the extending direction of the stopper structure 13 may also have an angular offset due to the manufacturing or optical consideration, and is not the true vertical direction. The stopper structure 13 does not contact the upper surface of the sensing chip 44, so that an interspace is present between the stopper structure 13 and the sensing chip 44. That is, the stopper structure 13 cooperates with the transceiving unit 90 to divide the chamber 11 of the sensing module into a receiving chamber 11B and an emitting chamber 11A being respectively disposed beneath the receiving window 12 and the transmitting window 14 and partially communicating with each other, so that the light sensing region 40 is disposed in the receiving chamber 11B, and the light reference region 30 and the light-emitting unit 20 are disposed in the emitting chamber 11A. The stopper structure 13 can further restrict more reference light L2, coming from the emitting chamber 11A, from reaching or entering the light sensing region 40 in the receiving chamber 11B to prevent the light sensing region 40 from generating a stray optical signal according to the reference light L2, so that the stray light interference of the emitting chamber 11A to the receiving chamber 11B can be decreased. That is, the stray light interference, caused by the light-emitting unit 20 in the emitting chamber 11A, to the light sensing region 40 in the receiving chamber 11B can be decreased. The stopper structure 13 has a serrate structure, and forms an integrally formed structure together with the body 16. The serrate structure has multiple inclined surfaces facing the light reference region 30 and reflecting the stray light rightward, so that the stray light cannot enter the light sensing region 40, and the multiple stray light eliminating effects can be provided. Therefore, the stopper structure 13 does not divide the chamber 11 into two spaces or entities dis-communicated from each other. Such the design can be better controlled in the package process owing to the following reasons. A mold is used to form the inverse U-shaped structure upon packaging, the circumference of the inverse U-shaped structure needs to contact the substrate 50 to form a periphery 15 of the cap 10. However, if the sawtooth of the stopper structure 13 needs to directly contact the sensing chip 44, then the tolerance requirement needs to very high, and the sawtooth has a tip that tends to be easily damaged. So, in the actual production, the stopper structure 13 needs to be configured to be separated from the sensing chip 44 by a gap to simplify the manufacturing process and enhance the structural stability. Meanwhile, it is also possible to prevent the difference between the environment conditions of the two chambers (e.g., the temperature rise caused by the light-emitting unit) from getting too high and thus to prevent the property difference between the reference pixel and the sensing pixel from getting too high.

It is worth noting that the light sensing region 40 includes the angular light-guiding structure (see FIGS. 3 to 6). Because the angular light-guiding structure of the light sensing region 40 can further precisely control the to-be-received specific angle of light, it is possible to further stop other stray light from entering the sensing pixel 41. In addition, the stopper structure 13 may have no serrate structure, but have the rectangular structure at the viewing angle of FIG. 7A, wherein the rectangular structure is still separated from the sensing chip 44 in the longitudinal direction to provide another option.

Referring to FIG. 7B, this example is similar to FIG. 7A except for the difference that the light reference region 30 includes the angular light-guiding structure (see FIGS. 3 to 6). Because the angular light-guiding structure of the light reference region 30 can further precisely control the to-be-received specific angle of light, the incident angle of the to-be-received reference light L2 can be further precisely controlled.

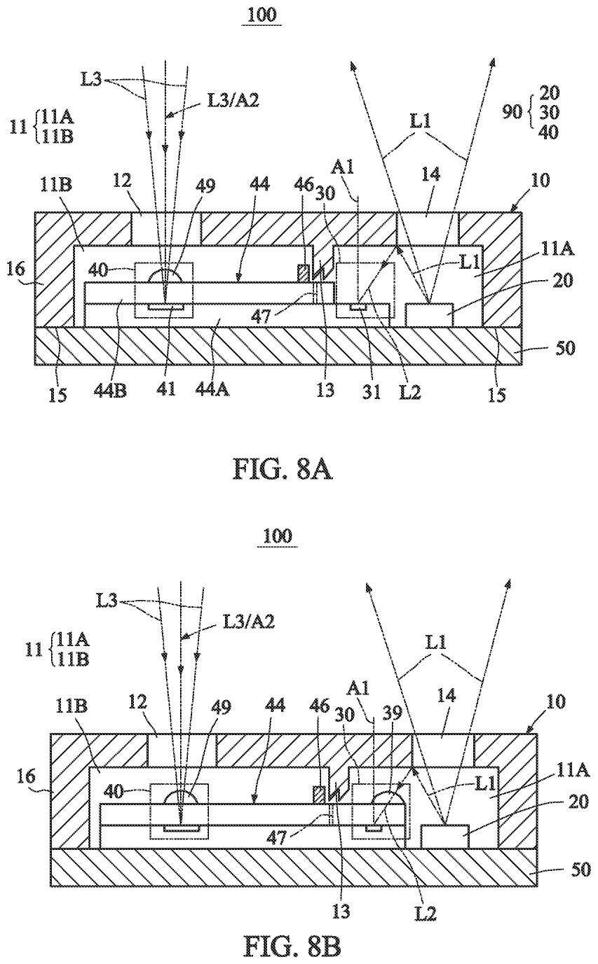

Referring to FIGS. 8A and 8B, the two examples are similar to those of FIGS. 7A and 7B, respectively, except for the difference that the TOF optical sensing module 100 further includes a second stopper structure 46 connected to the sensing chip 44 and disposed between the first optical axis A1 and the second optical axis A2, or disposed between the light sensing region 40 and the light reference region 30. The second stopper structure 46 is separated from the cap 10 in the longitudinal direction, and the second stopper structure 46 is separated from the stopper structure 13 in a horizontal direction. Of course, the extending direction of the second stopper structure 46 may also have an angular offset due to the manufacturing or optical consideration, and is not the true vertical direction. The stopper structure 13 and the second stopper structure 46 stop or restrict the reference light L2 from reaching the light sensing region 40. Therefore, the second stopper structure 46 can further prevent the stray light, passing through the stopper structure 13, from entering the light sensing region 40, and the multiple stray light eliminating effects can be provided. The advantage of the gap brought by the separation configuration is also the better control upon manufacturing.

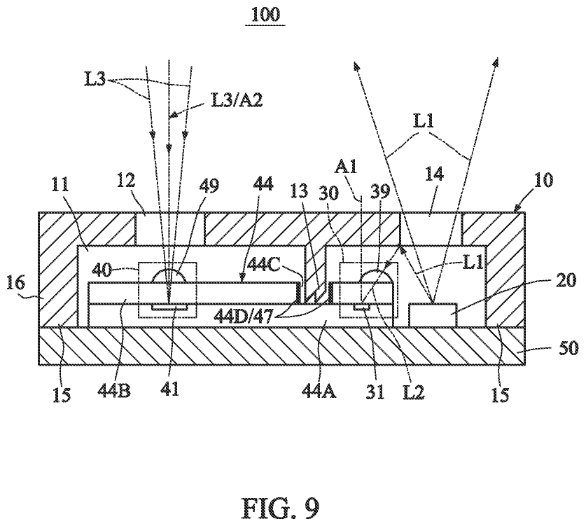

Referring to FIG. 9, the light sensing region 40 and the light reference region 30 may share the pixel substrate 44A, but a portion of the light-guiding structure 44B may be omitted or eliminated between the light reference region 30 and the light sensing region 40. That is, that portion of the light-guiding structure 44B is formed with a slot 44C, so that the pixel substrate 44A is exposed from the slot 44C. In this case, the stopper structure 13 may extend into the slot 44C to achieve the light-obstructing effect. In addition, two opposite sidewalls 44D defining the slot 44C may have two longitudinal light blocking structures, respectively 47 to prevent the stray light, coming from the light-guiding structure 44B, from being outputted to the light sensing region 40.

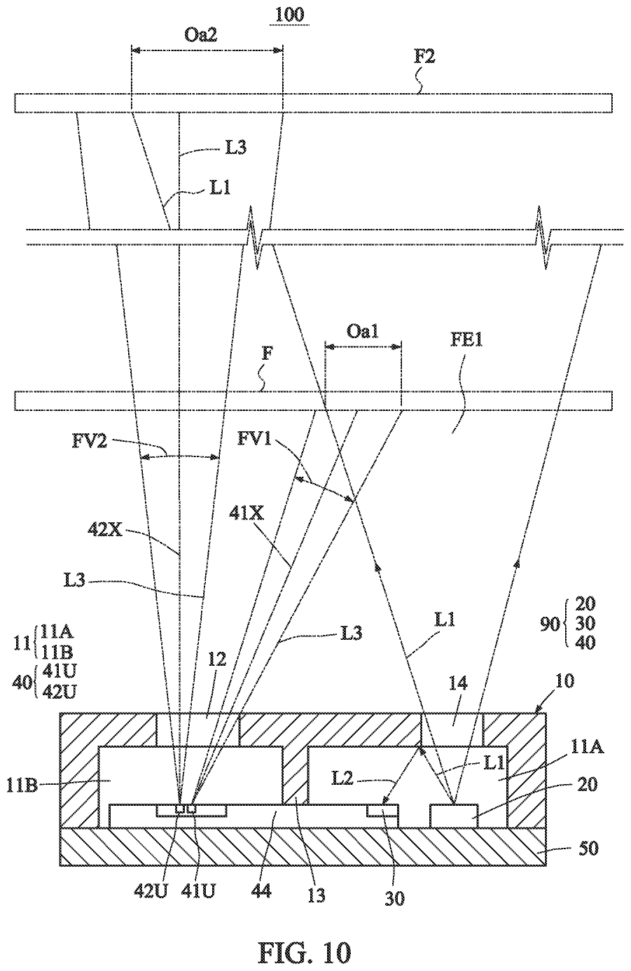

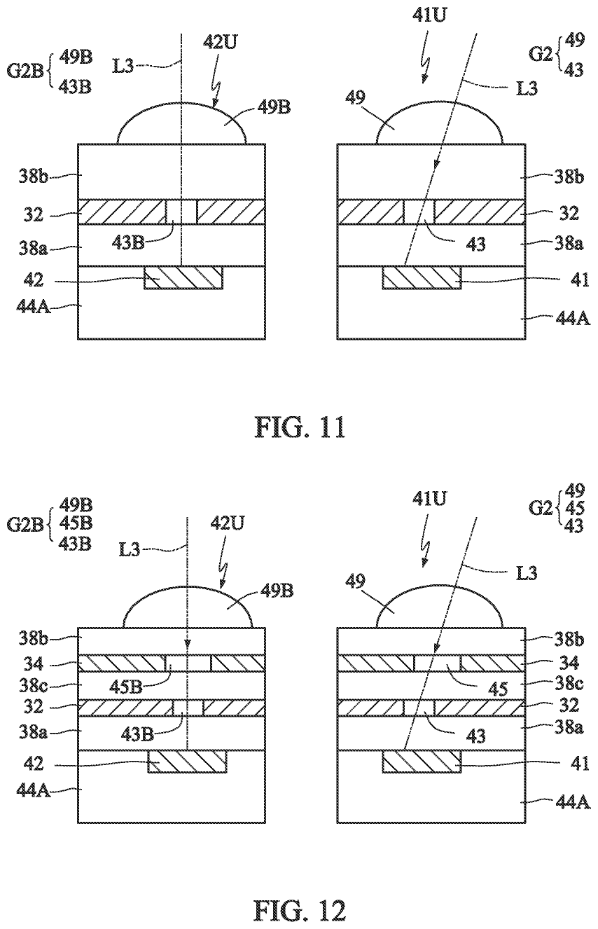

FIG. 10 is a schematic view showing a TOF optical sensing module 100 according to a preferred embodiment of this disclosure. FIG. 11 shows schematic structures of two sensing cells of FIG. 10. Referring to FIGS. 10 and 11, this example is similar to FIG. 2A except for the difference that sensing cells having different angular sensing-end light-guiding structures are adopted to sense objects located at different distances to provide the TOF optical sensing module with multiple FOVs.

The light-emitting unit 20 has an emitting field FE1, and outputs the detection light L1 through the transmitting window 14. The light sensing region 40 includes multiple sensing cells 41U and 42U respectively having the angular sensing-end light-guiding structure G2 and a second angular sensing-end light-guiding structure G2B different from each other to provide different angular ranges of FOVs FV1 and FV2. For example, the range of the FOV FV1 falls in the right half portion on the right side of the normal of the sensing cell 41U, and the range of the FOV FV2 falls in the left and right sides on the left side of the normal of the sensing cell 42U, wherein this disclosure is not restricted thereto. Thus, configuring the FOVs of the sensing cells can achieve the sensing function for sensing the objects respectively located at a long-distance position and a short-distance position, for example, at a same time instant or different time instants. Referring to FIG. 10, the sensing cells 41U and 42U sense the sensing light L3 reflected by different objects F and F2 from different distances through the receiving window 12 in a same mode or different modes to obtain the electric sensing signal.

Referring to FIG. 11, the sensing cell 41U (42U) in this embodiment includes: at least a sensing pixel 41 (42) formed on the pixel substrate 44A; a first light-obstructing layer 32 being disposed above the sensing pixel 41 (42) and having at least a first sensing aperture 43 (43B); and at least a sensing micro-lens 49 (49B) disposed above the first light-obstructing layer 32. In addition, a transparent dielectric layer 38a is disposed between the sensing pixel 41 (42) and the first light-obstructing layer 32, and a transparent dielectric layer 38b is disposed between the sensing micro-lens 49 (49B) and the first light-obstructing layer 32. Thus, the sensing micro-lenses 49 and 49B can respectively work in conjunction with the first sensing apertures 43 and 43B to provide different angular ranges of FOVs FV1 and FV2 for the sensing pixels 41 and 42.

In a short-distance sensing mode, the detection light L1 passes through the transmitting window 14, travels by a distance, then irradiates the object F, and is then reflected by the object F to make the object F output the sensing light L3. The sensing light L3 passes through the sensing micro-lens 49, the transparent dielectric layer 38b, the first sensing aperture 43 and the transparent dielectric layer 38a and enters the sensing pixel 41 of the sensing cell 41U. In a long-distance sensing mode, the detection light L1 passes through the transmitting window 14, then irradiates the object F2, and is then reflected by the object F2 to make the object F2 output the sensing light L3. The sensing light L3 passes through the sensing micro-lens 49B, the transparent dielectric layer 38b, the first sensing aperture 43B and the transparent dielectric layer 38a and then enters the sensing pixel 42 of the sensing cell 42U. It is understandable that the configurations of the aperture and the micro-lens are illustrated as only an embodiment without limiting this disclosure thereto because other angular collimating structures may also be adopted to achieve the similar effects of different angular ranges of FOVs FV1 and FV2 as long as the central optical axes 41X and 42X of the sensing cells 41U and 42U do not parallel with each other and are directed to appropriate orientation angles.

Referring to the example of FIG. 10, the FOV FV1 of the sensing cell 41U and the FOV FV2 of the sensing cell 42U do not have an overlapped portion. The FOV FV1 and the emitting field FE1 have a partial overlap region Oa1 on the object F, so the sensing cell 41U can sense the sensing light L3 from the object F. The FOV FV2 and the emitting field FE1 have no overlap region on the object F, so the sensing cell 42U cannot sense the sensing light L3 from the object F. On the other hand, the FOV FV1 and the emitting field FE1 have no overlap region on the object F2, so the sensing cell 41U cannot sense the sensing light L3 from the object F2; and the FOV FV2 and the emitting field FE1 have a partial overlap region 0a2 on the object F2, so the sensing cell 42U can sense the sensing light L3 from the object F2.

FIG. 12 shows schematic structures of modified examples of the two sensing cells of FIG. 11. Referring to FIG. 12, this example is similar to FIG. 11 except for the difference that the sensing cell 41U (42U) further has a transparent dielectric layer 38c and a second light-obstructing layer 34. The second light-obstructing layer 34 further has a second sensing aperture 45 (45B) working in conjunction with the first sensing aperture 43 (43B) to achieve the light guiding and restricting functions. The second light-obstructing layer 34 is separated from the first light-obstructing layer 32 by the transparent dielectric layer 38c to provide an appropriate gap. In this example, the advanced light blocking effect can be provided. Of course, in still another example, a peripheral light blocking layer (not shown) may be provided to surround the sensing micro-lens 49 (49B) and prevent stray light interference from the periphery of the micro-lens.

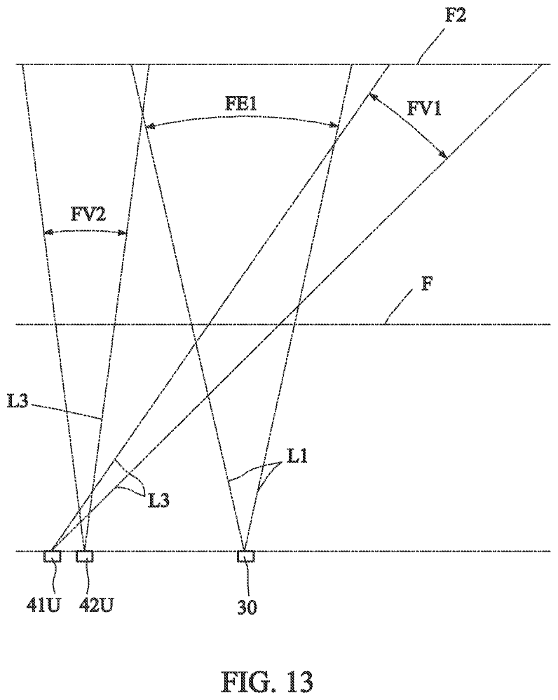

FIG. 13 is a schematic view showing light paths of a modified example of FIG. 10. Referring to FIG. 13, the FOVs FV1 and FV2 partially overlap with each other, so that the sensing cell 41U can sense the objects at a shorter distance and a longer distance. In addition, as shown in FIG. 13, the FOV FV1 and the emitting field FE1 overlap with each other on the object F, but do not overlap with each other on the object F2; and the FOV FV2 and the emitting field FE1 overlap with each other on the object F2, but do not overlap with each other on the object F.

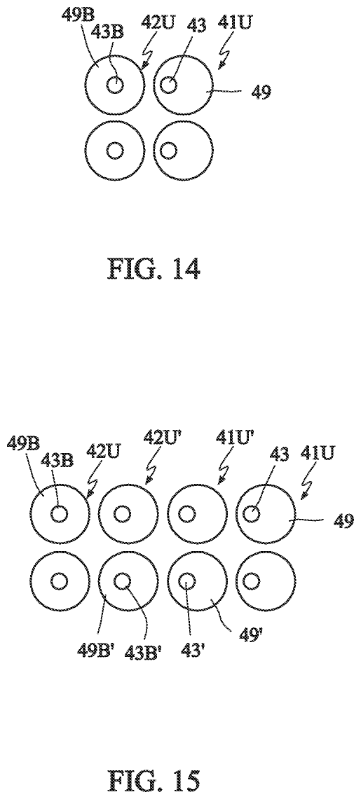

FIGS. 14 and 15 show layouts of two examples of sensing cells. Referring to FIG. 14, the sensing cells 41U and 42U are alternately arranged in a two-dimensional array. For the central optical axes of the micro-lens and the aperture, the offset from the first sensing aperture 43 of the sensing cell 41U to the sensing micro-lens 49 is different from the offset from the first sensing aperture 43B of the sensing cell 42U to the sensing micro-lens 49B, so that two objects located at two different field angles (distance ranges) can be sensed. Referring to FIG. 15, for the central optical axes of the micro-lens and the aperture, the offset vector from the first sensing aperture 43 to the sensing micro-lens 49, the offset vector from the sensing aperture 43′ of the sensing cell 41U′ to the sensing micro-lens 49′, the offset vector from the sensing aperture 43B′ of the sensing cell 42U′ to the sensing micro-lens 49B′, and the offset vector from the first sensing aperture 43B to the sensing micro-lens 49B may vary progressively, so that four objects at different field angles (distance ranges) can be sensed. Of course, one sensing cell without offset may also be provided to function as one cell of the gradual arrangement.

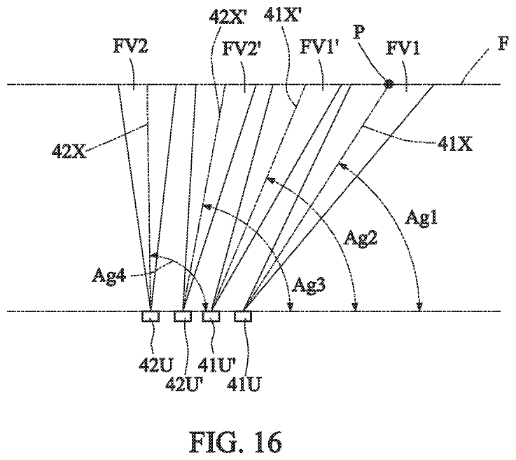

FIG. 16 is a schematic view showing FOVs of sensing cells. The configuration of FIG. 15 can be used to generate multiple sensing cells 41U, 41U′, 42U′ and 42U having different angular ranges of FOVs FV1, FV1′, FV2′ and FV2 shown in FIG. 16. The sensing cells 41U, 41U′, 42U′ and 42U are respectively arranged in a progressive (ascending or descending) manner according to the orientation angles Ag1, Ag2, Ag3 and Ag4 of the central optical axes 41X, 41X′, 42X′ and 42X of the FOVs FV1, FV1′, FV2′ and FV2, wherein the orientation angles may be defined with respect to the horizontal line. Thus, more objects at more distance ranges can be sensed. In addition, the oblique distance from the central optical axis to the sensing cell may also be converted into the perpendicular distance according to different orientation angles. For example, the distance from the sensing cell 41U to the object F is equal to the distance from the sensing cell 41U to the point P multiplied by sin(Ag1) to correct the error of the oblique distance.

It is worth noting that all the above embodiments can be combined, replaced or modified interactively as appropriate to provide various combination effects. The TOF optical sensing module can be applied to various electronic apparatuses, such as a mobile phone, a tablet computer, a camera and/or a wearable computer device capable of being attached to clothes, a shoe, a watch, glasses or any other arbitrary wearable structure. In some embodiments, the TOF optical sensing module or the electronic apparatus itself may be installed in traffic tools, such as a steamship and a vehicle, a robot or any other movable structure or machine.

With the TOF optical sensing module of the embodiments, at least an angular light-guiding structure and an optional stray light eliminating structure can be properly configured to effectively isolate the noise interference from the sensing pixel, so that the distance sensing result becomes more stable and accurate for associated applications. In addition, the stopper structure is formed on the inner side of the package cap, so that the manufacturing process can be easily controlled and simplified, the structural stability can be enhanced, the stray light interference and the thermal interference can be decreased, and the SNR of the sensing pixel can be increased. In addition, using different angular light-guiding structures of the same optical sensing module can provide multiple distance ranges of sensing effects and obtain the distance information of objects at a short distance, a medium distance and a long distance (or even more distance ranges) so that the distance information can be used in diversified applications.

While this disclosure has been described by way of examples and in terms of preferred embodiments, it is to be understood that this disclosure is not limited thereto. To the contrary, it is intended to cover various modifications. Therefore, the scope of the appended claims should be accorded the broadest interpretation so as to encompass all such modifications.

What is claimed is:

1. A time of flight (TOF) optical sensing module, comprising:
a substrate;
a cap comprising a body, and a receiving window and a transmitting window both connected to the body, wherein the body and the substrate commonly define a chamber; and
a transceiving unit being disposed in the chamber and comprising:
a light sensing region being disposed beneath the receiving window and comprising an angular sensing-end light-guiding structure and at least a sensing pixel, wherein the angular sensing-end light-guiding structure is configured to stop reference light, coming from the chamber and a location beneath the transmitting window, from entering the sensing pixel, but allow sensing light to be received by the sensing pixel through the receiving window to generate an electric sensing signal.

2. The TOF optical sensing module according to claim 1, wherein the transceiving unit further comprises a light-emitting unit being disposed beneath the transmitting window and outputting detection light, wherein a portion of the detection light irradiates an object disposed above the cap through the transmitting window, and is reflected by the object to output the sensing light, and another portion of the detection light is reflected within the cap to generate the reference light.

3. The TOF optical sensing module according to claim 2, wherein the light sensing region further comprises:
at least a first light-obstructing layer being disposed above the sensing pixel and having
a first sensing aperture; and
at least a sensing micro-lens disposed above the first light-obstructing layer, wherein the sensing light is focused onto the sensing pixel through the sensing micro-lens and the first sensing aperture.

4. The TOF optical sensing module according to claim 3, wherein the light sensing region further comprises:
a second light-obstructing layer being disposed above the first light-obstructing layer and having a second sensing aperture, wherein the sensing light is focused onto the sensing pixel through the sensing micro-lens, the second sensing aperture and the first sensing aperture.

5. The TOF optical sensing module according to claim 4, wherein the light sensing region further comprises:
a third light-obstructing layer disposed above the second light-obstructing layer and on a periphery of the sensing micro-lens to block stray light from entering the sensing pixel.

6. The TOF optical sensing module according to claim 2, wherein the transceiving unit further comprises:
a light reference region, which is disposed in the chamber and receives the reference light to generate an electric reference signal.

7. The TOF optical sensing module according to claim 6, wherein the light reference region comprises an angular reference-end light-guiding structure and at least a reference pixel, wherein the angular reference-end light-guiding structure guides the reference light to the reference pixel to make the reference pixel generate the electric reference signal.

8. The TOF optical sensing module according to claim 7, wherein the angular reference-end light-guiding structure comprises:
at least a first light-obstructing layer being disposed above the reference pixel and having a first reference aperture; and
at least a reference micro-lens disposed above the first light-obstructing layer, wherein a center line of the reference micro-lens is not aligned with a center line of the first reference aperture, and the reference light is focused onto the reference pixel through the reference micro-lens and the first reference aperture.

9. The TOF optical sensing module according to claim 8, wherein the angular reference-end light-guiding structure further comprises:
a second light-obstructing layer being disposed above the first light-obstructing layer and having a second reference aperture, wherein the center line of the reference micro-lens, the center line of the first reference aperture and a center line of the second reference aperture are not aligned with each other, and the reference light is focused onto the reference pixel through the reference micro-lens, the second reference aperture and the first reference aperture.

10. The TOF optical sensing module according to claim 9, wherein the angular reference-end light-guiding structure further comprises:
a third light-obstructing layer disposed above the second light-obstructing layer and on a periphery of the reference micro-lens to block stray light from entering the reference pixel.

11. The TOF optical sensing module according to claim 6, wherein the light reference region and the light sensing region are formed in a sensing chip, and the sensing chip comprises:
a first light-obstructing layer having a first reference aperture and a first sensing aperture, which are respectively disposed above a reference pixel of the light reference region and the sensing pixel; and
a reference micro-lens and a sensing micro-lens, which are respectively disposed above the first reference aperture and the first sensing aperture, wherein a center line of the reference micro-lens is not aligned with a center line of the first reference aperture, and the reference light is focused onto the reference pixel through the reference micro-lens and the first reference aperture, wherein the sensing light is focused onto the sensing pixel through the sensing micro-lens and the first sensing aperture.

12. The TOF optical sensing module according to claim 11, wherein the sensing chip further comprises:
a second light-obstructing layer being disposed above the first light-obstructing layer and having a second reference aperture and a second sensing aperture, wherein the center line of the reference micro-lens, the center line of the first reference aperture and a center line of the second reference aperture are not aligned with each other, and the reference light is focused onto the reference pixel through the reference micro-lens, the second reference aperture and the first reference aperture, wherein the sensing light is focused onto the sensing pixel through the sensing micro-lens, the second sensing aperture and the first sensing aperture.

13. The TOF optical sensing module according to claim 12, wherein the sensing chip further comprises:
a third light-obstructing layer disposed above the second light-obstructing layer and on a. periphery of the reference micro-lens and on a periphery of the sensing micro-lens to block stray light from entering the reference pixel and the sensing pixel,

14. The TOF optical sensing module according to claim 11, wherein the sensing chip further comprises a longitudinal light blocking structure disposed between the light reference region and the light sensing region.

15. The TOF optical sensing module according to claim 11, wherein the cap further comprises a stopper structure disposed between the transmitting window and the receiving window to divide the chamber into a receiving chamber and an emitting chamber respectively disposed beneath the receiving window and the transmitting window and partially communicating with each other in conjunction with the transceiving unit to decrease stray light interference of the emitting chamber to the receiving chamber.

16. The TOF optical sensing module according to claim 15, further comprising a second stopper structure being connected to the sensing chip and disposed between the light reference region and the light sensing region, wherein the second stopper structure is separated from the cap in a longitudinal direction, the second stopper structure is separated from the stopper structure in a horizontal direction, and the stopper structure and the second stopper structure restrict the reference light from reaching the light sensing region.

17. The TOF optical sensing module according to claim 15, wherein the stopper structure has a serrate structure and forms an integrally formed structure together with the body.

18. The TOF optical sensing module according to claim 15, wherein the sensing chip further comprises a pixel substrate and an angular light-guiding structure, the angular light-guiding structure is disposed on the pixel substrate and has a slot so that the pixel substrate is exposed. from the slot, and the stopper structure extends into the slot.

19. The TOF optical sensing module according to claim 18, wherein two opposite sidewalls defining the slot have two longitudinal light blocking structures, respectively.

20. The TOF optical sensing module according to claim 6, wherein the light reference region comprises at least a reference pixel, but has no angular reference-end. light-guiding structure corresponding to the reference pixel.

21. The TOF optical sensing module according to claim 2, wherein the cap further comprises a stopper structure disposed between the transmitting window and the receiving window to divide the chamber into a receiving chamber and an emitting chamber respectively disposed beneath the receiving window and the transmitting window and partially communicating with each other in conjunction with the transceiving unit to decrease stray light interference of the emitting chamber to the receiving chamber.

22. The TOF optical sensing module according to claim 1, wherein the transceiving unit comprises multiple sensing cells, and the sensing cells respectively have the angular sensing-end light-guiding structure and a second angular sensing-end light-guiding structure to provide multiple fields of view (FOVs) having different angular ranges.

23. The TOF optical sensing module according to claim 22, wherein the transceiving unit further comprises:
a light-emitting unit being disposed beneath the transmitting window and outputting detection light, wherein a portion of the detection light irradiates an object disposed above the cap through the transmitting window, and is reflected by the object to output the sensing light, and another portion of the detection light is reflected within the cap to generate the reference light; and
a light reference region being disposed in the chamber and receives the reference light.

24. The TOF optical sensing module according to claim 22, wherein the sensing cells comprises:
multiple sensing pixels being formed on a pixel substrate and comprising the at least a sensing pixel;
a first light-obstructing layer being disposed above the sensing pixels and having sensing apertures; and
multiple sensing micro-lenses disposed above the first light-obstructing layer, wherein the sensing micro-lenses work in conjunction with the sensing apertures to provide the FOVs having the different angular ranges for the sensing pixels, respectively.

25. The TOF optical sensing module according to claim 22, wherein central optical axes of the sensing cells are not parallel to each other.

26. The TOF optical sensing module according to claim 22, wherein the sensing cells comprises a first sensing cell and a second sensing cell for sensing the sensing light, reflected by different objects from different distances, through the receiving window in a same mode or different modes, the objects comprise an object and a second object, the FOV of the first sensing cell overlaps with an emitting field of a light-emitting unit of the transceiving unit on the object but does not overlap with the emitting field on the second object, and the FOV of the second sensing cell does not overlap with the emitting field on the object but overlaps with the emitting field on the second object.

27. The TOF optical sensing module according to claim 22, wherein the sensing cells having the FOVs having the different angular ranges are arranged alternately in a two-dimensional. array.

28. The TOF optical sensing module according to claim 22, wherein the sensing cells having the FOVs having the different angular ranges are gradually arranged according to orientation angles of central optical axes of the FOVs.

29. The TOF optical sensing module according to claim 22, wherein the FOVs partially overlap with each other or one another.

30. The TOF optical sensing module according to claim wherein the FOVs do not overlap with each other.
